(19) United States
(12) Patent Application Publication
(10) Pub. No.: US 2026/0085421 A1
(43) Pub. Date: Mar. 26, 2026

(54) LASER HEATING ARRANGEMENTS FOR INJECTION GAS ACTIVATION, AND RELATED PROCESSING CHAMBERS, APPARATUS, AND METHODS

(71) Applicant: Applied Materials, Inc., Santa Clara, CA (US)

(72) Inventors: Ala MORADIAN, Sunnyvale, CA (US); Shu-Kwan LAU, Sunnyvale, CA (US)

(21) Appl. No.: 18/893,596

(22) Filed: Sep. 23, 2024

(51) Int. Cl. C23C 16/455

(52) U.S. Cl. CPC C23C 16/4557

(57) ABSTRACT

The present disclosure relates to pre-heating process gases for activation, such as for low-temperature processing, and related chamber kits, methods, and processing chambers. In one or more embodiments, a substrate processing chamber includes a chamber body at least partially defining an internal volume, a substrate support disposed in the internal volume, and a flow inlet assembly operable to flow a gas into the internal volume. The flow inlet assembly includes an injector, an opening formed in the injector, and a flow guide disposed in the opening. The flow guide includes an inner surface and an outer surface, and the flow guide is in fluid communication with the internal volume. The flow inlet assembly includes one or more heating elements disposed within the opening, and an absorptive mass disposed within the flow guide.

### BACKGROUND

### FIELD

The present disclosure relates to pre-heating process gases for activation, such as for low-temperature processing, and related chamber kits, methods, and processing chambers.

### DESCRIPTION OF THE RELATED ART

Semiconductor substrates are processed for a wide variety of applications, including the fabrication of integrated devices and microdevices. One method of processing substrates includes depositing a material, such as a semiconductor material or a conductive material, on an upper surface of the substrate. For example, epitaxy is one deposition process that deposit films of various materials on a surface of a substrate in a processing chamber. During processing, various parameters can affect the uniformity of material deposited on the substrate.

Operations (such as epitaxial deposition operations) involve one or more processing gases to be heated in order to be activated (such as cracked). Relatively higher processing temperatures can involve unintended dopant diffusion and/or hindered device performance. In addition, high processing temperatures can damage already structures formed on the substrate. However, it can be difficult to activate processing gases at relatively lower temperatures. Moreover, different gases can involve different activation temperatures.

Therefore, a need exists for improved apparatuses and methods in semiconductor processing.

### SUMMARY

The present disclosure relates to pre-heating process gases for activation, such as for low-temperature processing, and related chamber kits, methods, and processing chambers.

In one or more embodiments, a substrate processing chamber includes a chamber body at least partially defining an internal volume, a substrate support disposed in the internal volume, and a flow inlet assembly operable to flow a gas into the internal volume. The flow inlet assembly includes an injector, an opening formed in the injector, and a flow guide disposed in the opening. The flow guide includes an inner surface and an outer surface, and the flow guide is in fluid communication with the internal volume. The flow inlet assembly includes one or more heating elements disposed within the opening, and an absorptive mass disposed within the flow guide.

In one or more embodiments, a flow inlet assembly includes a flow guide including a sleeve, one or more heating elements disposed outside of the flow guide, and an absorptive mass disposed within the flow guide. The flow inlet assembly includes one or more supports extending between the flow guide and the absorptive mass to support the absorptive mass.

In one or more embodiments, a method of pre-heating one or more process gases includes heating an absorptive mass disposed within a flow guide. The heating includes emitting an electromagnetic radiation to an absorptive mass such that the absorptive mass absorbs the electromagnetic radiation. The method includes flowing one or more process gases into the flow guide, and heating the one or more process gases by flowing the one or more process gases between the absorptive mass and the flow guide.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1A is a partial schematic side cross-sectional view of a processing chamber, according to one or more embodiments

FIG. 1B is an enlarged partial schematic side cross-sectional view of the flow inlet assembly shown in FIG. 1, according to one or more embodiments.

FIGS. 2A – 2E are partial schematic front cross-sectional view of a flow inlet assembly, according to embodiments.

FIGS. 3A – 3D are partial schematic isometric views of a flow inlet assembly, according to embodiments.

FIG. 4 is a schematic block diagram view of a method of heating one or more process gases, according to one or more embodiments.

FIG. 5 is a schematic partial cross sectional top view of the processing chamber, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure relates to heating arrangements for injection gas activation, and related processing chambers, apparatus, chamber kits, and methods. In one or more embodiments, a heating arrangement is used to pre-heat process gases for low-temperature processing (such as low temperature deposition (e.g., epitaxy), pre-cleaning, etching, and/or chamber cleaning).

The disclosure contemplates that terms such as “couples,” “coupling,” “couple,” and “coupled” may include but are not limited to embedding, bonding, welding, fusing, melting together, interference fitting, and/or fastening such as by using bolts, threaded connections, pins, and/or screws. The disclosure contemplates that terms such as “couples,” “coupling,” “couple,” and “coupled” may include but are not limited to integrally forming. The disclosure contemplates that terms such as “couples,” “coupling,” “couple,” and “coupled” may include but are not limited to direct coupling and/or indirect coupling, such as indirect coupling through components such as links, blocks, and/or frames.

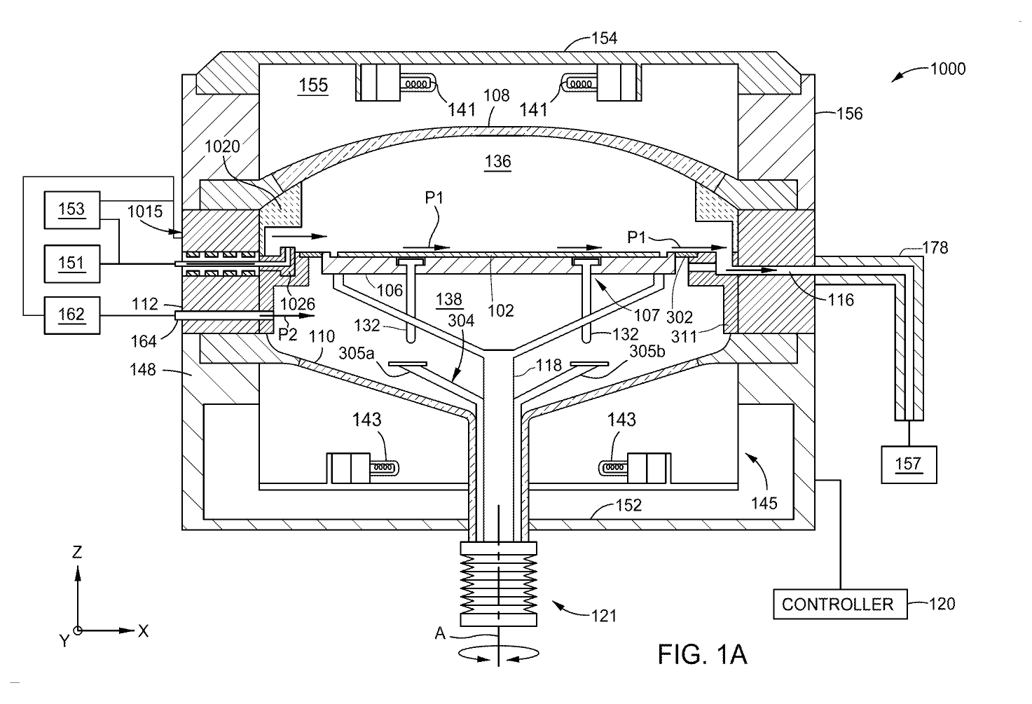

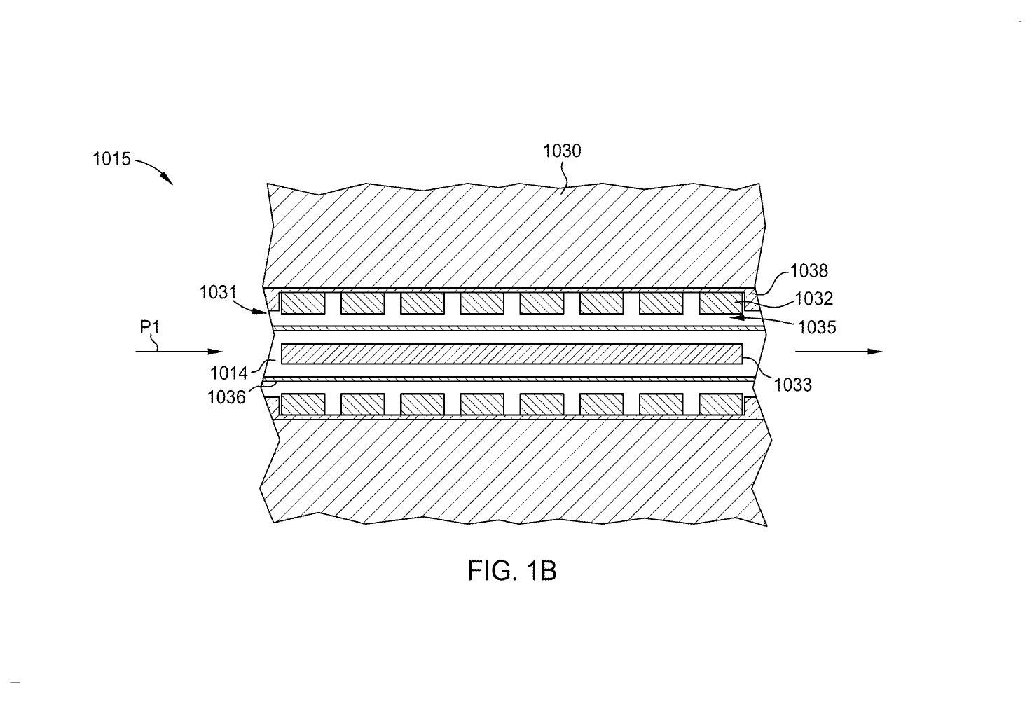

FIG. 1A is a partial schematic side cross-sectional view of a processing chamber 1000, according to one or more embodiments. The processing chamber 1000 is a deposition chamber. In one or more embodiments, the processing chamber 1000 is an epitaxial deposition chamber. In one or more embodiments, the processing chamber 1000 is utilized to grow an epitaxial film on a substrate 102. The processing chamber 1000 creates a cross-flow of precursors across a top surface of the substrate 102. The processing chamber 1000 is shown in a processing condition in FIG. 1.

The processing chamber 1000 includes an upper body 156, a lower body 148 disposed below the upper body 156, a flow module 112 disposed between the upper body 156 and the lower body 148. The upper body 156, the flow module 112, and the lower body 148 form a chamber body. A flow inlet assembly 1015 is disposed in between the flow module 112 and the upper body 156. The flow inlet assembly 1015 is show and described in greater detail in FIG. 1B. Disposed within the chamber body is a substrate support 106, an upper plate 108 (such as an upper window and/or an upper dome), a lower plate 110 (such as a lower window and/or a lower dome), a plurality of upper heat sources 141, and a plurality of lower heat sources 143. As shown, a controller 120 is in communication with the processing chamber 1000 and is used to control processes and methods, such as the operations of the methods described herein. The present disclosure contemplates that each of the heat sources described herein can include one or more of: lamp(s), resistive heater(s), light emitting diode(s) (LEDs), and/or laser(s). The present disclosure contemplates that other heat sources can be used.

The substrate support 106 is disposed between the upper plate 108 and the lower plate 110. The substrate support 106 includes a support face that supports the substrate 102. The plurality of upper heat sources 141 are disposed between the upper window and a lid 154. The plurality of upper heat sources 141 form a portion of the upper heat source module 155. The lid 154 may include a plurality of sensors disposed therein or thereon for measuring the temperature within the processing chamber 1000. The plurality of lower heat sources 143 are disposed between the lower plate 110 and a floor 152. The plurality of lower heat sources 143 form a portion of a lower heat source module 145. In one or more embodiments, the upper plate 108 is an upper dome and is formed of an energy transmissive material, such as quartz. In one or more embodiments, the lower plate 110 is a lower dome and is formed of an energy transmissive material, such as quartz. A pre-heat ring 302 is disposed outwardly of the substrate support 106. A stop 304 includes a plurality of arms 305a, 305b that each include a lift pin stop on which at least one of the lift pins 132 can rest when the substrate support 106 is lowered (e.g., lowered from a process position to a transfer position).

The internal volume has the substrate support 106 disposed therein. The substrate support 106 includes a top surface on which the substrate 102 is disposed. The substrate support 106 is attached to a shaft 118. The shaft 118 is connected to a motion assembly 121. The motion assembly 121 includes one or more actuators and/or adjustment devices that provide movement and/or adjustment for the shaft 118 and/or the substrate support 106.

The substrate support 106 may include lift pin perforations 107 disposed therein. The lift pin perforations 107 are sized to accommodate a lift pin 132 for lifting of the substrate 102 from the substrate support 106 either before or after a deposition process is performed.

The chamber body includes a first liner 1020 and a second liner 311. The second liner 311 is disposed below the first liner 1020. The pre-heat ring 302 is supported on a ledge of the second liner 311

The flow inlet assembly 1015 (which can define at least part of one or more sidewalls of the processing chamber 1000) includes one or more flow guides 1014 in fluid communication with the processing volume 136 of the internal volume. The one or more flow guides 1014 are in fluid communication with one or more flow inlets (such as one or more flow gaps between the first liner 1020 and the second liner 311). One or more inject blocks 1026 having one or more flow openings formed therein can be disposed in the one or more flow openings. The flow inlet assembly 1015 is fluidly connected to one or more process gas sources 151 and one or more cleaning gas sources 153. The purge gas inlet(s) 164 are fluidly connected to one or more purge gas sources 162. The one or more gas exhaust outlets 116 are fluidly connected to an exhaust pump 157. One or more process gases supplied using the one or more process gas sources 151 can include one or more reactive gases (such as one or more of silicon-containing, phosphorus-containing, and/or germanium-containing gases, and/or one or more carrier gases (such as one or more of nitrogen (N2) and/or hydrogen (H2)), and/or one or more etchant gases (such as one or more of hydrogen and/or chlorine (such as hydrochloric acid (HCl)). One or more purge gases supplied using the one or more purge gas sources 162 can include one or more inert gases (such as one or more of argon (Ar), helium (He), and/or nitrogen (N2)). One or more cleaning gases and/or etching gases supplied using the one or more cleaning gas sources 153 can include one or more of hydrogen and/or chlorine (such as hydrochloric acid (HCl)). In one or more embodiments, the one or more process gases include silicon hydrides (such as one or more silanes and/or one or more chlorinated silanes), germanium (such as germane (GeH4)), boron (such as diborane (B2H6)), and/or phospine (PH3).

The one or more gas exhaust outlets 116 are further connected to or include an exhaust system 178. The exhaust system 178 fluidly connects the one or more gas exhaust outlets 116 and the exhaust pump 157. The exhaust system 178 can assist in the controlled deposition of a layer on the substrate 102. The exhaust system 178 is disposed on an opposite side of the processing chamber 1000 relative to the flow module 112.

During a deposition operation (e.g., an epitaxial growth operation), the one or more process gases P1 flow through the flow inlet assembly 1015 and into the processing volume 136 to flow horizontally over the substrate support 106 and the substrate 102 and to the one or more gas exhaust outlets 116. The one or more purge gases P2 are supplied from one or more purge gas sources 162 to the purge volume 138 through one or more purge gas inlets 164. The one or more purge gases P2 flow simultaneously with the flowing of the one or more process gases P1. The one or more process gases P1 are exhausted through exhaust gaps between the first liner 1020 and the second liner 311, and through the one or more gas exhaust outlets 116. The one or more purge gases P2 are exhausted through the same exhaust gaps between the first liner 1020 and the second liner 311, and through the same one or more gas exhaust outlets 116 as the one or more process gases P1. The present disclosure contemplates that that one or more purge gases P2 can be separately exhausted through one or more second gas exhaust outlets that are separate from the one or more gas exhaust outlets 116.

FIG. 1B is an enlarged partial schematic side cross-sectional view of the flow inlet assembly 1015 shown in FIG. 1, according to one or more embodiments.

The flow inlet assembly 1015 includes an injector 1030. An opening 1031 extends through the injector 1030. One or more flow guides 1014 extend through the opening 1031. In one or more embodiments, each flow guide 1014 includes a sleeve surrounding the outer surface 1036 of the flow guide 1014. The sleeve can include different geometries and different shapes, such as a cylindrical shape or a rectangular shape (such as in the shape of a rectangle or a square). One or more heating elements 1032 are disposed within a housing 1038. The housing 1038 is disposed within the opening 1031 outside of the one or more flow guides 1014 within a heating region 1035. An absorptive mass 1033 is disposed within the one or more flow guides 1014. One or more process gases P1 flow from one or more process gas sources 151 through the one or more flow guides 1014. The one or more process gases P1 continue flowing through the one or more flow guides 1014 into the processing volume 136. The one or more process gases P1 contact and flow around the absorptive mass 1033 as they flow through the one of more flow guides 1014. The one or more process gases P1 can include one or more deposition gases, one or more pre-clean gases, and/or one or more etchant/cleaning gases. In one or more embodiments, the absorptive mass 1033 is a rod.

The heating elements 1032 are disposed within the housing 1038. The housing 1038 is disposed within the heating region 1035. The heating elements 1032 can be coupled to the injector 1030 and/or an outer surface 1036 of the one or more flow guides 1014. In one or more embodiments, the heating elements 1032 include one or more vertical-cavity surface emitting lasers (VCSL). In one or more embodiments, the heating elements 1032 include one or more light emitting diodes (LED). The one or more heating elements 1032 are configured to emit electromagnetic radiation, such as infrared radiation or ultraviolet radiation. In one or more embodiments, the one or more heating elements 1032 are configured to emit laser light. Other heaters, such as lamp(s) and/or resistive heater(s), are contemplated for the one or more heating elements 1032.

The electromagnetic radiation is directed towards the absorptive mass 1033. The one or more flow guides 1014 are formed of a transparent material, such as a clear quartz, to allow the electromagnetic ration to pass through the one or more flow guides 1014 and contact the absorptive mass 1033. The absorptive mass is formed of an opaque material configured to absorb electromagnetic radiation. The opaque material has thermal properties that facilitate quickly and efficiently heating the absorptive mass 1033. The opaque material has an emissivity that is greater than or equal to 0.45 at a processing temperature, such as 0.75 or higher at the processing temperature. In one or more embodiments, the emissivity of the opaque material is within a range of 0.45 to 0.9, such as 0.75 to 0.9, or higher, at the processing temperature. In one or more embodiments, the emissivity is within a range of 0.75 to 0.85, such as about 0.80. Other emissivity values are contemplated. The processing temperature can be, for example, 600 degrees Celsius or 1,000 degrees Celsius. Other processing temperatures are contemplated.

The opaque material has a thermal conductivity that is less than 100.0 W/m-K, such as less than 10.0 W/m-K, at a processing temperature. In one or more embodiments, the thermal conductivity of the opaque material is less than 5.0 W/m-K at the processing temperature, such as less than 3.0 W/m-K at the processing temperature. In one or more embodiments, the thermal conductivity of the opaque material is about 1.5 at the processing temperature. Other thermal conductivity values are contemplated. The opaque material includes silicon carbide (SiC), graphite coated with SiC, and/or opaque quartz (such as black quartz, grey quartz, and/or white quartz). In one or more embodiments, the absorptive mass 1033 is formed of SiC.In one or more embodiments, the SiC is pure SiC (e.g., having an atomic percentage of at least 99% for silicon and carbon) formed using chemical vapor deposition (CVD). It is believed that the pure SiC is resistant to process gases (e.g., corrosion resistant) and facilitates high absorption and emissivity.

During a processing operation the one or more heating elements 1032 emit electromagnetic radiation which is absorbed by the absorptive mass 1033. The electromagnetic radiation increases the temperature of the absorptive mass 1033. The one or more process gases P1 flow from the from one or more process gas sources 151 and into the one or more flow guides 1014. As the one or more process gases P1 flow through the one or more flow guides 1014, the one or more process gases P1 are heated by the absorptive mass 1033. The one or more process gases P1 continue to flow out through the one or more flow guides 1014 into the processing volume 136. A first temperature of the one of more process gases P1 before the one or more process gases P1 enter the one or more flow guides 1014 is lower than a second temperature of the one or more process gases P1 after the one or more process gases exit the one or more flow guides 1014.

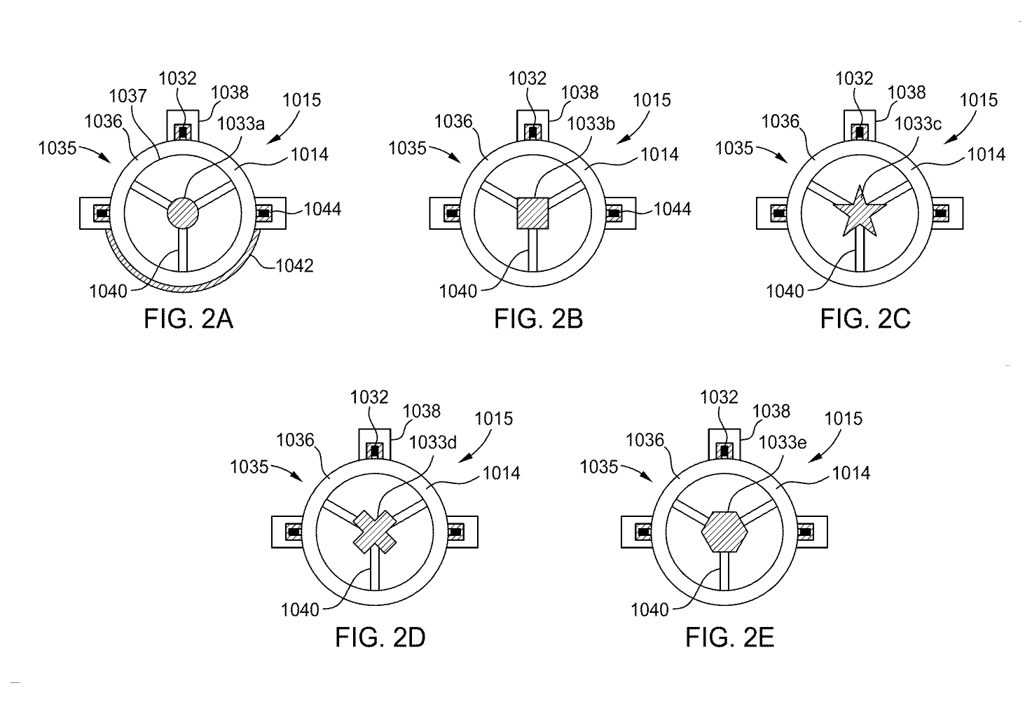

FIGS. 2A – 2E are partial schematic front cross-sectional view of a flow inlet assembly 1015, according to embodiments.

FIG. 2A shows an absorptive mass 1033a having a circular cross section. The cross sections described herein can be solid (as shown) or hollow. The absorptive mass 1033a is supported by one or more supports 1040. The one or more supports 1040 extend from an inner surface 1037 of the flow guide 1014 to the absorptive mass 1033. The one or more supports 1040 hold the absorptive mass 1033a in place within the flow guide 1014.The one or more supports 1040 are formed of a transparent material. In one or more embodiments, the one or more supports 1040 are formed of a clear quartz. In one or more embodiments, the one or more supports 1040 are formed of the same material as the flow guide 1014. In one or more embodiments, the one or more supports 1040 and the flow guide 1014 are integrally formed as a monolithic body. The one or more supports 1040 can be welded, bonded, or fused to the absorptive mass 1033a and the flow guide 1014. In one or more embodiments, the one or more supports 1040 includes a plurality of plates (three are shown as an example) azimuthally spaced from each other. The plurality of plates extend radially between an outer surface of the absorptive mass 1033a and an inner surface of the sleeve.

In one or more embodiments, one or more lamp reflectors 1044 are disposed within the housing 1038. The one or more lamp reflectors 1044 are formed of a reflective material. The one or more lamp reflectors 1044 help direct the electromagnetic energy from the one or more heating elements 1032 disposed within the housing towards the absorptive mass 1033a. In one or more embodiments, the flow guide 1014 includes a reflector 1042 disposed on the outer surface 1036 of the flow guide 1014. The reflector 1042 is formed of a reflective material that can be coated on the outer surface 1036. The reflector 1042 helps direct the electromagnetic energy from the one or more heating elements 1032 towards the absorptive mass 1033a. It should be understood that although the reflector 1042 is shown disposed below the one or more heating elements 1032, the reflector 1042 can be disposed anywhere around the outer surface 1036 of the flow guide 1014. The reflector 1042 can be used in conjunction with the one or more lamp reflectors 1044 as shown in FIG. 2A. In one or more embodiments, multiple reflectors 1042 are disposed around the outer surface 1036 of the flow guide 1014. In one or more embodiments, one or more reflectors 1042 coat the outer surface 1036 of the flow guide 1014 azimuthally. In one or more embodiments, the one or more reflectors 1042 at least coat entireties of portions of the outer surface 1036 in-between the one or housings 1038 coupled to the outer surface 1036. In one or more embodiments, the one or more reflectors coat all of the outer surface 1036.

FIGS. 2B – 2E are examples of other shapes that the cross section of the absorptive mass 1033 may have.

FIG. 2B shows a flow inlet assembly 1015 including an absorptive mass 1033b having a rectangular cross section, according to one or more embodiments. The rectangular shape includes rectangle shapes or square shapes.

FIG. 2C shows a flow inlet assembly 1015 including an absorptive mass 1033c having a star shaped cross section, according to one or more embodiments.

FIG. 2D shows a flow inlet assembly 1015 including an absorptive mass 1033d having an x-shaped cross section, according to one or more embodiments.

FIG. 2E shows a flow inlet assembly 1015 including an absorptive mass 1033e having a polygonal shaped cross section, according to one or more embodiments. In one or more embodiments, the polygonal shape is a hexagon, as shown in FIG. 2E. Other shapes, such as an octagon, can be used.

It should be understood that FIGS. 2A – 2E are shown for exemplary purposes and that the absorptive mass 1033 can have any shape. In addition, it should be understood that the embodiments of the flow inlet assembly 1015 shown in FIGS. 2B – 2E can include the reflector 1042 and/or the lamp reflectors 1044 as shown and described in FIG. 2A. The absorptive mass 1033 can have a variety of shapes and/or features (such as grooves, recesses, extensions, and/or fins) to facilitate increased surface area for gas activation while facilitating beneficial gas flow (such as laminar flow) about the absorptive mass 1033.

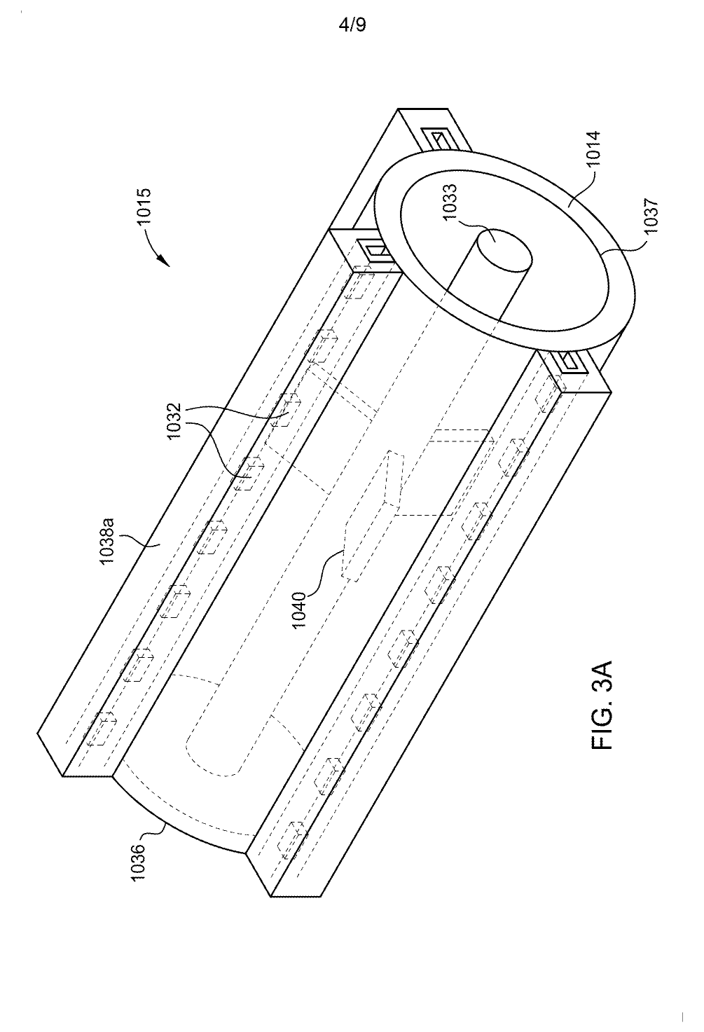

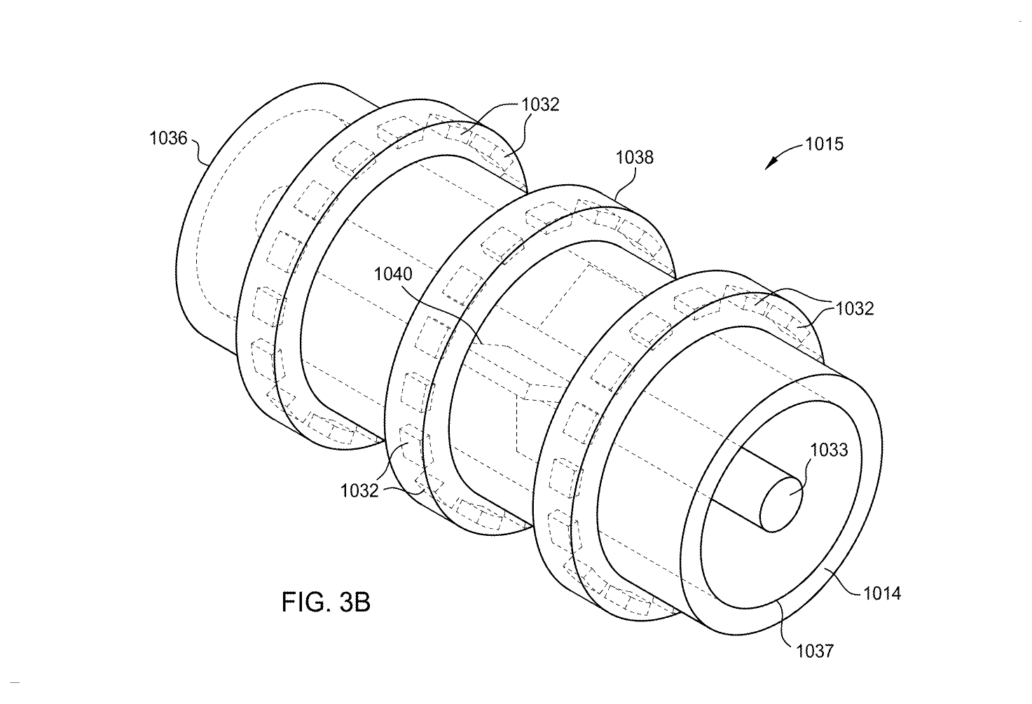

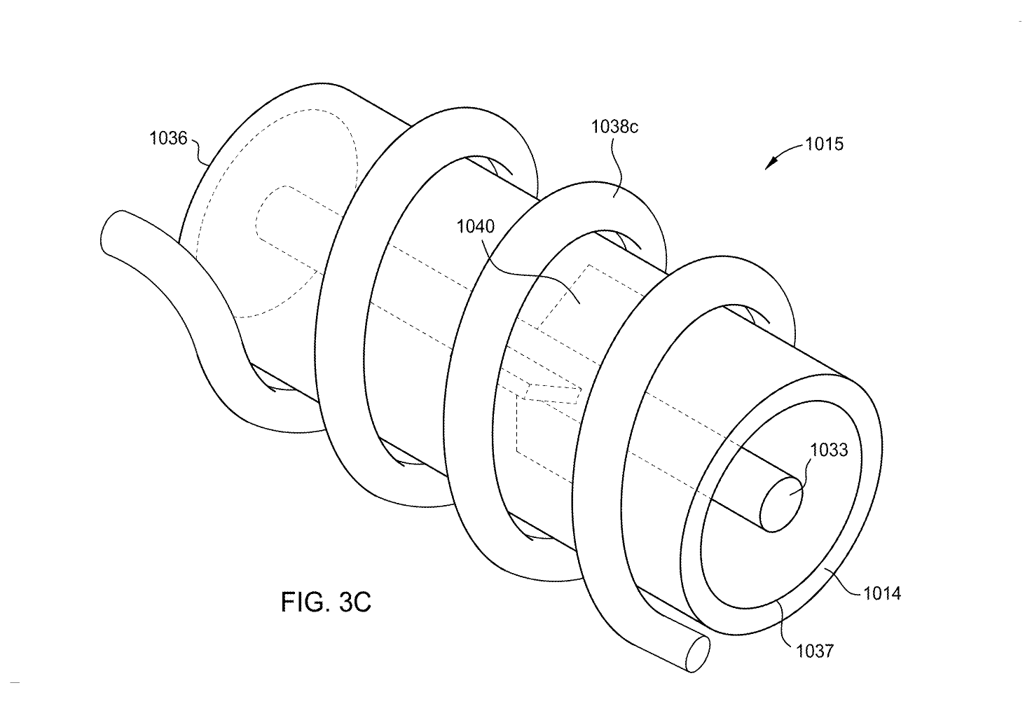

FIGS. 3A – 3D are partial schematic isometric views of a flow inlet assembly 1015, according to embodiments. FIG. 3A shows the flow inlet assembly 1015 having one or more heating elements 1032 arranged respectively in a plurality housings 1038a, according to one or more embodiments. In one or more embodiments, the housings 1038a are in the shapes of bars, such as U-shaped bars. The housings 1038a shown in FIG. 3A are bars disposed on the outer surface 1036 of the flow guide 1014. Each housing 1038a can include one or more heating elements 1032. The heating elements 1032 may include VCSLs or LEDs. In one or more embodiments, the heating element 1032 includes an ultraviolet (UV) lamp extending through the housing 1038a.

FIGS. 3B - 3D are examples of different arrangements for the one or more housings 1038, according to one or more embodiments.

FIG. 3B shows a flow inlet assembly 1015 including one or more housings 1038b having a ring-shaped geometry, according to one or more embodiments. The one or more housings 1038b in FIG. 3B may be disposed around the outer surface 1036 of the flow guide 1014. The ring-shaped housings 1038b are spaced from each other along a linear length of the flow guide 1014, which can define a plurality of heating stages for the one or more process gases P1.

FIG. 3C shows a flow inlet assembly 1015 including one or more housings 1038c having a spiral shape, according to one or more embodiments. The one or more housings 1038c in FIG. 3C may be disposed around the outer surface 1036 of the flow guide 1014, and can spiral around the outer surface 1036 (such as along a helical pattern). FIG. 3C shows a flow inlet assembly 1015 including one or more housings 1038c surrounding the flow guide 1014, according to one or more embodiments. The one or more housings 1038c in FIG. 3C may be disposed around the outer surface 1036 of the flow guide 1014.

FIG. 3D shows a flow inlet assembly 1015 including a plurality of housings 1038d having a having a bar shape, according to one or more embodiments. The one or more housings 1038d in FIG. 3D may be disposed around the outer surface 1036 of the flow guide 1014. The one or more housings 1038d are staggered from each other along a linear length of the outer surface 1036 of the flow guide 1014. FIG. 3D shows the flow inlet assembly 1015 including the one or more housings 1038d staggered from each other along a circumference of the outer surface 1036 of the flow guide 1014. The one or more housings 1038d in FIG. 3D may be disposed around the outer surface 1036 of the flow guide 1014.

It should be understood that FIGS. 3A – 3D are shown for exemplary purposes and that the one or more housings 1038 can include any number of housings 1038, and that the housings 1038 can include any type of shape. In addition, it should be understood that the embodiments of the flow inlet assembly 1015 shown in FIGS. 3A – 3D can include the reflector 1042 and/or the reflectors 1044 as shown and described in FIG. 2A.

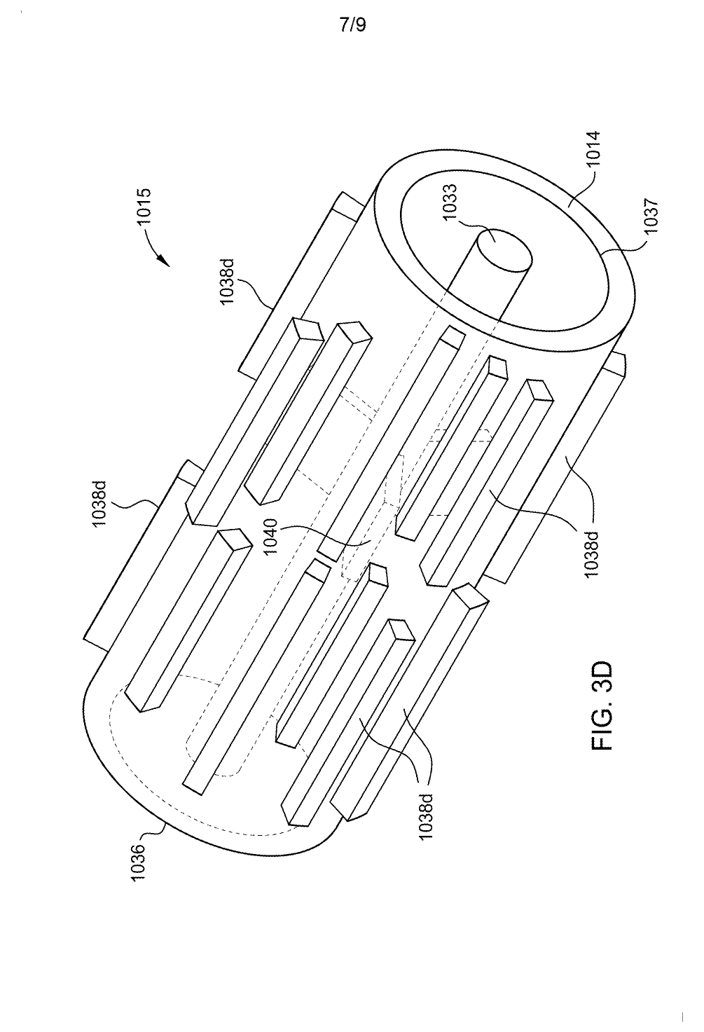

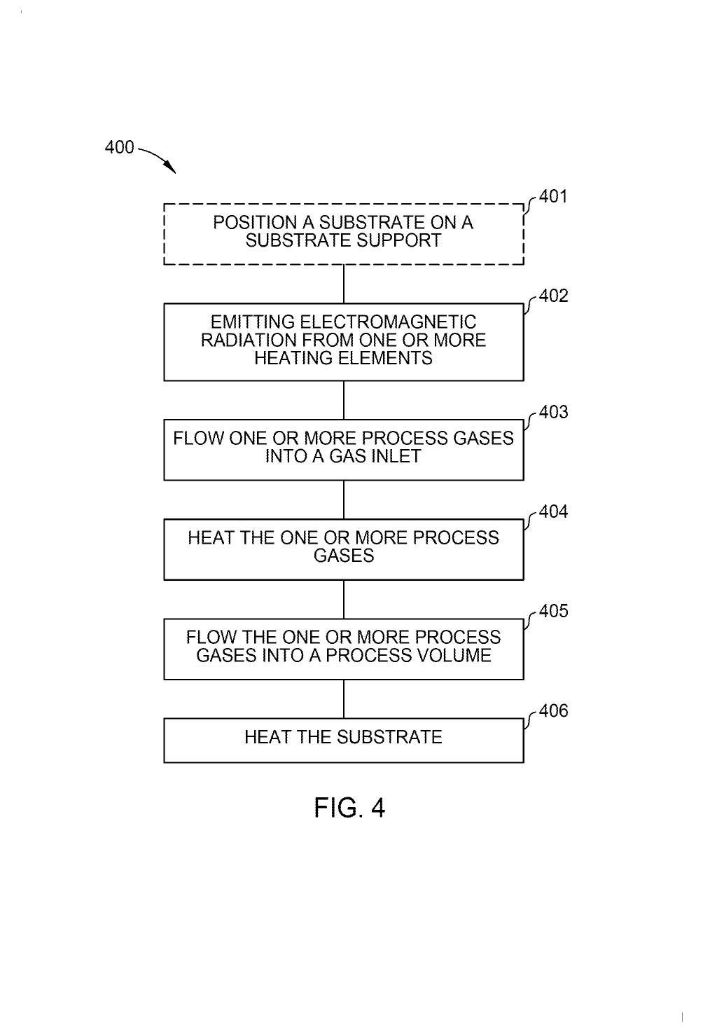

FIG. 4 is a schematic block diagram view of a method 400 of heating one or more process gases, according to one or more embodiments. In one or more embodiments, the method 400 is performed using one or more components of the processing chamber 1000 described herein.

Optional operation 401 of method 400 includes positioning a substrate on a substrate support in a processing volume of a processing chamber. In one or more embodiments, the positioning includes moving a substrate support and/or a plurality of lift pins relative to each other to land the substrate on the substrate support.

Operation 402 of the method 400 includes emitting electromagnetic radiation from one or more heating elements. The electromagnetic radiation is directed towards an absorptive mass disposed within a flow guide. The absorptive mass absorbs the electromagnetic radiation, which causes the temperature of the absorptive mass to increase.

Operation 403 of the method 400 includes flowing one or more process gases from one or more process gas sources, into the flow guide of operation 402. The one or more process gases enter the flow guide at a first temperature. The one or more process gases can include one or more reactive gases (such as one or more of silicon-containing, phosphorus-containing, and/or germanium-containing gases, one or more carrier gases (such as one or more of nitrogen (N2) and/or hydrogen (H2)), and/or one or more etchant gases (such as one or more of hydrogen and/or chlorine (such as hydrochloric acid (HCl)).

Operation 404 of the method 400 includes heating the one or more process gases of operation 403. The one or more process gases are heated by flowing the one or more process gases around the absorptive mass from operation 402. In one or more embodiments, the one or more process gases are heated to a second temperature higher than the first temperature. The second temperature can be lower than the first temperature. In one or more embodiments, the second temperature is within a range of 50 degrees Celsius to 500 degrees Celsius, such as 100 degrees Celsius to 450 degrees Celsius. The first temperature and/or the second temperature can vary depending, for example, on process recipes.

Operation 405 of the method 400 includes flowing the one or more process gases over the substrate. The one or more process gases flow from the flow guide into processing volume. The one or more process gases flow across the substrate while within the processing volume.

Operation 406 includes heating the substrate to a substrate temperature. In one or more embodiments, the substrate temperature is less than 550 degrees Celsius, such as less than 500 degrees Celsius. In one or more embodiments, the substrate temperature is 450 degrees Celsius or less, such as 400 degrees Celsius or less, for example 350 degrees Celsius.

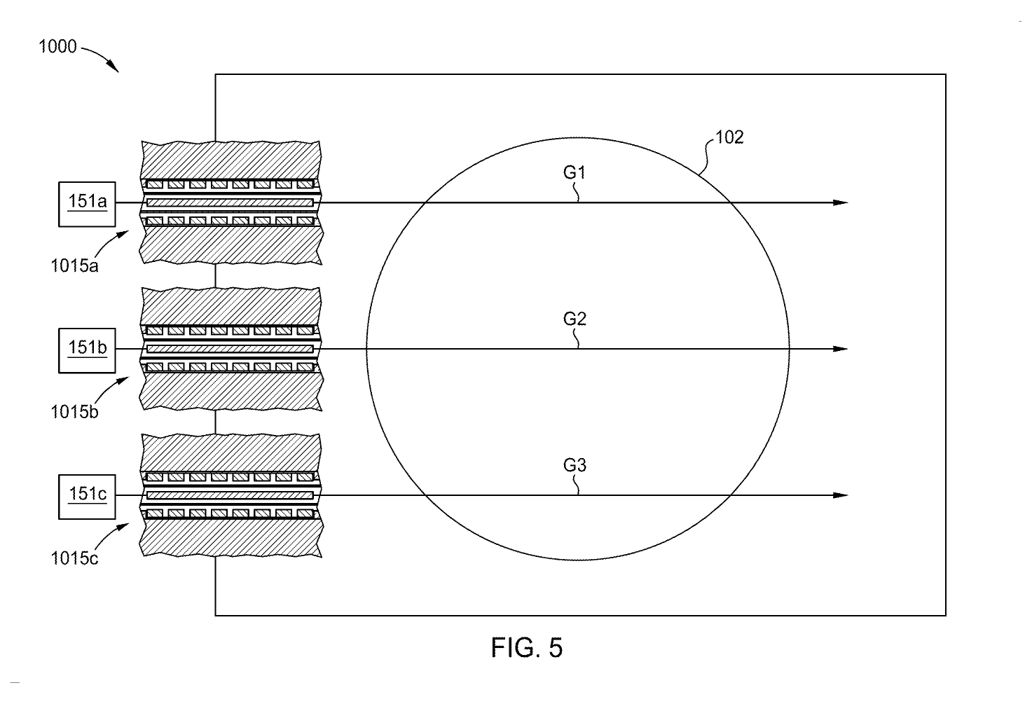

FIG. 5 is a schematic partial cross sectional top view of the processing chamber 1000, according to one or more embodiments.

The processing chamber 1000 shown in FIG. 5 includes a plurality of flow inlet assemblies including a first flow inlet assembly 1015a, a second flow inlet assembly 1015b, and a third flow inlet assembly 1015c. The first flow inlet assembly 1015a is fluidly connected to a first process gas source 151a. The second flow inlet assembly 1015b is fluidly connected to a second process gas source 151b. The third flow inlet assembly 1015c is fluidly connected to a third process gas source 151c. The first process gas source 151a supplies a first gas G1. The second process gas source 151b supplies a second gas G2. The third process gas source 151c supplies a third gas G3. The first gas G1 can include one or more deposition gases, one or more pre-clean gases, and/or one or more etchant and/or chamber cleaning gases. The second gas G2 can include one or more deposition gases, one or more pre-clean gases, and/or one or more etchant and/or chamber cleaning gases. The third gas G3 can include one or more deposition gases, one or more pre-clean gases, and/or one or more etchant and/or chamber cleaning gases. In one or more embodiments, the first gas G1, the second gas G2, and/or the third gas G3 have different compositions. For example, the first gas G1, the second gas G2, and/or the third gas G3 can be different parts of a process recipe. The gases G1, G2, and/or G3 may include silicon source(s) such as silane, disilane, dichlorosilane, trichlorosilane, or combination(s) thereof. The gases G1, G2, and/or G3 may include dopant source(s) (such as an n-type dopant source or a p-type dopant source), for example germane (GeH₄), diborane (B₂H₆ ), phosphine (PH₃), borinic acid (Bu₃B), tin(IV) chloride (SnCl₄), germanium tetrachloride (GeCl₄), or combination(s) thereof. The gases G1, G2, and/or G3 may include etchant sourc(es) such as hydrogen chloride (HCl), chlorine gas (Cₗ₂), phosphorus trichloride (PCl₃), arsenic trichloride (AsCl₃), diiodo silane (SiH₂I₂), or combination(s) thereof.

In one or more embodiments, the first flow inlet assembly 1015a, the second flow inlet assembly 1015b, and/or the third flow inlet assembly 1015c can be controlled independently from one another. The first flow inlet assembly 1015a can be controlled to preheat the first gas G1 to a first temperature. The second flow inlet assembly 1015b can be controlled to preheat the first gas G1 to a second temperature. The third flow inlet assembly 1015c can be controlled to preheat the third gas G3 to a third temperature. Using for example the controller 120, the composition and/or flow rate of the respective gases G1-G3 flowed respectively to the inlet assemblies 1015a-1015c can be independently controlled. Using for example the controller 120, the respective temperatures to which the respective gases G1-G3 are preheated can be independently controlled. For example, the first temperature, the second temperature, and/or the third temperature can be different from each other. The present disclosure contemplates that the gases G1-G3 can respectively flow at different times, such as at different stages of a process recipe.

After the first gas G1, the second gas G2, and the third gas G3 are preheated, the first gas G1, the second gas G2, and the third gas G3 are flowed from the flow inlet assemblies 1015a-1-15c respectively, into the processing volume 136. The first gas G1, the second gas G2, and the third gas G3 then flow across the substrate 102 within the processing volume 136. For example, in one or more embodiments the first gas G1 is a dopant gas (such as diborane (B₂H₆)) and the second gas G2 is a deposition gas (such as trichlorosilane (HCl₃Si)). The first gas G1 is preheated to the first temperature to be activated. The second gas G2 is heated to the second temperature. In one or more embodiments, the second temperature is higher than the first temperature to be activated. The present disclosure contemplates that the activation temperatures for the gases can depend on parameters (such as gas composition and gas flow rate, for example. In one or more embodiments the first gas G1, the second gas G2, and the third gas G3 are flowed simultaneously. In one or more embodiments the first gas G1, the second gas G2, and the third gas G3 are flowed into the processing volume 136 at separate times from one another.

The inlet assemblies 1015a-1015c can correspond to different zones of the substrate being processed. Three zones are shown, and a different number (such as five zones) are contemplated. In FIG. 5 cross sections of the flow inlet assemblies 1015a-1015c are shown for visual clarity purposes.

Benefits of the present disclosure include activation of one or more process gases for low temperature processing, increased deposition efficiency, and decreased maintenance and decreased cost. Benefits also include adjustability of activation, such as based on varying gas compositions and/or gas flow rates.

It is contemplated that one or more aspects disclosed herein may be combined. As an example, one or more aspects, features, components, operations and/or properties of the processing chamber 1000, the flow inlet assembly 1015, the injector 1030, the one or more flow guides 1014, the opening 1031, the one or more heating elements 1032, the housing 1038, the housings 1038a, the housings 1038b, the housings 1038c, the housing 1038d, the heating region 1035, the absorptive mass 1033, the absorptive mass 1033a, the absorptive mass 1033b, the absorptive mass 1033c, the absorptive mass 1033d, the absorptive mass 1033e, the one or more supports 1040, the one or more reflectors 1044, the one or more reflectors 1042, the flow inlet assemblies 1015a-1015c, and/or the method 400 may be combined. Moreover, it is contemplated that one or more aspects disclosed herein may include some or all of the aforementioned benefits.

While the foregoing is directed to embodiments of the present disclosure, other and further embodiments of the disclosure may be devised without departing from the basic scope thereof, and the scope thereof is determined by the claims that follow.

What is claimed is:

1. A substrate processing chamber, comprising:
a chamber body at least partially defining an internal volume;
a substrate support disposed in the internal volume;
a flow inlet assembly operable to flow a gas into the internal volume, the flow inlet assembly comprising:
an injector;
an opening formed in the injector;
a flow guide disposed in the opening, the flow guide comprising an inner surface and an outer surface, the flow guide being in fluid communication with the internal volume;
one or more heating elements disposed within the opening; and
an absorptive mass disposed within the flow guide.

2. The processing chamber of claim 1, wherein the one or more heating elements are disposed within a housing.

3. The processing chamber of claim 2, wherein the housing is coupled to the outer surface of the flow guide.

4. The processing chamber of claim 2, wherein the housing further comprises a reflector material disposed on the housing.

5. The processing chamber of claim 1, wherein the flow guide further comprises a reflector material disposed on the outer surface.

6. The processing chamber of claim 1, wherein the one or more heating elements comprise one or more of: one or more vertical-cavity surface emitting lasers or one or more light emitting diodes.

7. The processing chamber of claim 1, wherein the absorptive mass is formed of an opaque material.

8. The processing chamber of claim 1, wherein the absorptive mass is formed of silicon carbide, and the flow guide is formed of a transparent material comprising a clear quartz.

9. The processing chamber of claim 1, wherein the flow inlet assembly further comprises one or more supports extending from the inner surface of the flow guide and supporting the absorptive mass.

10. A flow inlet assembly comprising:
a flow guide including a sleeve ;
one or more heating elements disposed outside of the flow guide; and
an absorptive mass disposed within the flow guide; and
one or more supports extending between the flow guide and the absorptive mass to support the absorptive mass.

11. The flow inlet assembly of claim 10, further comprising a housing coupled to an outer surface of the sleeve, wherein the one or more heating elements are disposed within the housing.

12. The flow inlet assembly of claim 11, wherein the housing further comprises a reflector material disposed on the housing.

13. The flow inlet assembly of claim 10, wherein the flow guide further comprises a reflector material disposed on an outer surface of the sleeve.

14. The flow inlet assembly of claim 10, wherein the one or more heating elements comprise one or more of: one or more vertical-cavity surface emitting lasers or one or more light emitting diodes.

15. The flow inlet assembly of claim 10, wherein the absorptive mass is formed of silicon carbide.

16. The flow inlet assembly of claim 10, wherein the one or more supports include a plurality of plates azimuthally spaced from each other, and the plurality of plates extending radially between the absorptive mass and the sleeve.

17. The flow inlet assembly of claim 16, wherein the flow guide and the plurality of plates are formed of a clear quartz.

18. A method of pre-heating one or more process gases comprising:
heating an absorptive mass disposed within a flow guide, the heating comprising:
emitting an electromagnetic radiation to an absorptive mass such that the absorptive mass absorbs the electromagnetic radiation;
flowing one or more process gases into the flow guide; and
heating the one or more process gases by flowing the one or more process gases between the absorptive mass and the flow guide.

19. The method of claim 18 further comprising:
flowing the one or more process gases over a substrate positioned within an internal volume of a processing chamber.

20. The method of claim 18, wherein the one or more process gases include one or more of a deposition gas, a cleaning gas, or an etchant gas.
